(19) United States
(12) Patent Application Publication
(10) Pub. No.: US 2025/0120028 A1
(43) Pub. Date: Apr. 10, 2025

(54) DISPLAY DEVICE

(71) Applicant: LG Display Co., Ltd., Seoul (KR)

(72) Inventor: Jae Ho JUNG, Paju-si (KR)

(21) Appl. No.: 18/675,905

(22) Filed: May 28, 2024

(30) Foreign Application Priority Data
Oct. 10, 2023 (KR) 10-2023-0133984

(51) Int. Cl. H05K 5/03; H05K 7/20

(52) U.S. Cl. CPC H05K 5/03; H05K 7/20963

(57) ABSTRACT

An embodiment of the present specification discloses a display devices comprising: a housing with an opening formed on one side thereof; a display panel disposed in the opening; a first substrate disposed on the rear surface of the display panel; a first flexible film connecting the display panel and the first substrate; a second substrate disposed to be spaced apart from the first substrate; and a second flexible film connecting the first substrate and the second substrate, wherein the second substrate is more spaced apart from the display panel than the first substrate.

### CROSS-REFERENCE TO RELATED APPLICATION

This application claims priority to and the benefit of Korean Patent Application No. 10-2023-0133984, filed Oct. 10, 2023, the disclosure of which is incorporated herein by reference in its entirety.

### BACKGROUND

### Technical Field

The present disclosure relates to a display device.

### Description of the Related Art

Organic light emitting display devices reproduce images by emitting light using an organic light emitting diode (OLED) placed in each pixel according to an input image signal. The organic light emitting display devices have a fast response speed and high luminous efficiency, luminance, and viewing angle, and have an excellent contrast ratio and color reproducibility as it can express black grayscales in full black. No backlight unit is required for these organic light emitting display devices.

When the display device is driven, heat is generated in electronic elements, wiring, and the like disposed on the substrate of the display panel, and such heat affects the display panel. For example, the temperature distribution of the display panel becomes uneven depending on the position of the substrate, and when the temperature distribution of the display panel is uneven, the image quality of the image reproduced on the display panel deteriorates due to electronic elements having temperature characteristics.

When a separate member is used to reduce the heat effect on the display panel, there is an ineffective problem in terms of productivity, such as an increase in process cost, because the number of assembly man-hours increases by the separate member.

Accordingly, the development of a display device that can improve productivity structurally while minimizing the effect of heat generated from the substrate on the display panel is required.

### BRIEF SUMMARY

An embodiment provides a structurally improved display device to minimize the heat effect of heat generated from a substrate on a display panel.

An embodiment provides a structurally improved display device to improve productivity.

An embodiment provides a structurally improved display device to improve the assembly and heat dissipation performance of a substrate.

Objectives to be solved by embodiments are not limited to the objectives described above, and objectives which are not described above will be clearly understood by those skilled in the art from the following descriptions.

A display device according to an embodiment of the present specification includes a housing having an opening formed on one side thereof; a display panel disposed in the opening; a first substrate disposed on the rear surface of the display panel; a first flexible film connecting the display panel and the first substrate; a second substrate disposed to be spaced apart from the first substrate; and a second flexible film connecting the first substrate and the second substrate, wherein the second substrate is more spaced apart from the display panel than the first substrate.

A display device according to an embodiment of the present specification includes a housing having an opening formed on one side thereof; a display panel disposed in the opening; a first substrate disposed on the rear surface of the display panel; a first flexible film connecting the display panel and the first substrate; a second substrate disposed to be spaced apart from the first substrate; a second flexible film connecting the first substrate and the second substrate; and a cover glass disposed in front of the display panel, wherein the housing includes a housing body and a sidewall protruding from the edge of the housing body to contact the edge of the cover glass, and the second substrate is coupled to the housing body.

The embodiment may minimize the heat effect on the display panel by arranging the substrate having a relatively high heat dissipation among the two substrates more spaced apart from the display panel.

The embodiment may improve the dissipation of heat generated from the substrate by using a heat sink disposed in the housing.

The embodiment may improve assembly and fixing of the substrate by implementing a guide structure and a separation prevention structure in the housing.

The embodiment may prevent damage to the display panel due to assembly of the housing by fixing the housing to the cover glass disposed in front of the display panel, while minimizing the transfer of heat generated from the substrate to the display panel through the housing.

The embodiment may minimize the transfer of heat generated from the substrate to the display panel through the material of the housing.

The embodiment may improve display quality by minimizing non-uniformity with respect to temperature distribution in a display panel by using a plate made of a metal material.

The embodiment may improve the lifespan of the display panel by minimizing the heat effect on the display panel. Accordingly, it enables low-power driving of the production process in terms of reducing production energy.

Various useful advantages and effects of the embodiments are not limited to the above-described contents, and effects which are not described above will be clearly understood by those skilled in the art from the following descriptions.

### BRIEF DESCRIPTION OF THE SEVERAL VIEWS OF THE DRAWINGS

The above and other objects, features, and advantages of the present specification will become more apparent to those of ordinary skill in the art by describing exemplary embodiments thereof in detail with reference to the attached drawings, in which:

FIG. 1 is a perspective view illustrating a display device according to one embodiment of the present specification;

FIG. 2 is an exploded perspective view illustrating a display device according to one embodiment of the present specification;

FIG. 3 is a plan view illustrating a display device according to one embodiment of the present specification;

FIG. 4 is a cross-sectional view illustrating a cross section taken along line A-A in FIG. 3;

FIG. 5 is a cross-sectional view illustrating a housing of a display device according to one embodiment of the present specification;

FIG. 6 is a bottom perspective view illustrating a housing of a display device according to one embodiment of the present specification;

FIG. 7 is a block diagram schematically illustrating a configuration of a display device according to one embodiment of the present specification;

FIG. 8 is a cross-sectional view schematically illustrating a cross-sectional structure of a display area of a display device according to one embodiment of the present specification;

FIG. 9 is a perspective view illustrating a second substrate of a display device according to one embodiment of the present specification;

FIG. 10 is a bottom perspective view illustrating a second substrate of a display device according to one embodiment of the present specification;

FIG. 11 is a view illustrating an arrangement relationship between a housing and a second substrate of a display device according to one embodiment of the present specification;

FIG. 12 is an enlarged view of an area A of FIG. 11;

FIG. 13 is a view illustrating a heat sink of a display device according to one embodiment of the present specification;

FIG. 14 is a view illustrating a display device according to another embodiment of the present specification;

FIG. 15 is a view illustrating an arrangement relationship between a second substrate and a ground member of a display device according to another embodiment of the present specification; and

FIG. 16 is a view illustrating a cross-section of a ground member disposed in a display device according to another embodiment of the present specification.

### DETAILED DESCRIPTION

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The claims are not defined or limited by the disclosure.

In describing the present disclosure, detailed descriptions of known related technologies may be omitted so as not to unnecessarily obscure the subject matter of the present disclosure.

The terms such as “comprising,” “including,” “having” and “consisting of” used herein are generally intended to allow other components to be added unless the terms are used with the term “only.” References to the singular shall be construed to include the plural unless expressly stated otherwise.

When describing a positional or interconnected relationship between two components, such as “on top of,” “above,” “below,” “next to,” “connect or couple with,” “crossing,” “intersecting,” etc., one or more other components may be interposed between them unless “immediately” or “directly” is used.

When describing a temporal contextual relationship is described, such as “after,” “following,” “next to” or “before,” it may not be continuous on a time scale unless “immediately” or “directly” is used.

The terms “first,” “second” and the like may be used to distinguish components from each other, but the functions or structures of the components are not limited by ordinal numbers or component names in front of the components.

The following embodiments may be combined or associated with each other in whole or in part, and various types of interlocking and driving are technically possible. The embodiments may be implemented independently of each other or together in an interrelated relationship.

Terms used in the embodiments of the disclosure (including technical and scientific terms) are to be construed as they would be commonly understood by one of ordinary skill in the art to which the disclosure belongs, unless otherwise specifically defined and described, and commonly used terms, such as dictionary defined terms, are to be construed in light of their contextual meaning in the relevant art.

Hereinafter, preferred embodiments of the present disclosure will be described in detail with reference to the accompanying drawings.

In the recent information society, display devices have become increasingly important as visual information transmission media, and they are being improved to meet requirements such as low power consumption, thinness, weight reduction, high definition, and high efficiency.

The display device according to one embodiment of the present specification may reduce the effect of heat generated from the circuit boards on the display panel through two separated circuit boards and a structure that separates the circuit boards. Accordingly, by improving the lifespan of the display panel, it is possible to reduce greenhouse gas in terms of reducing production energy.

The display device according to one embodiment of the present specification may improve the lifespan of the display panel by uniformly implementing the temperature distribution of the display panel using a plate formed of a metal material.

The display device according to one embodiment of the present specification may improve heat dissipation performance of the circuit board through a heat sink coupled to the housing while improving assembly and fixing of the circuit board using the housing.

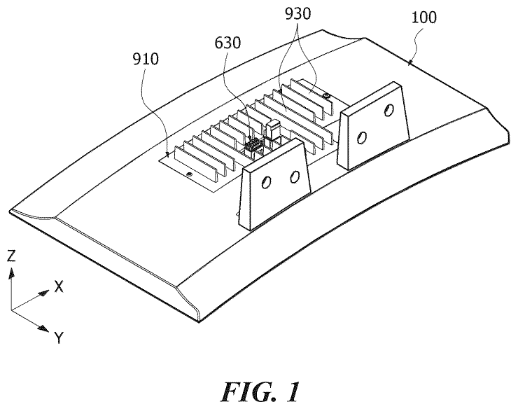

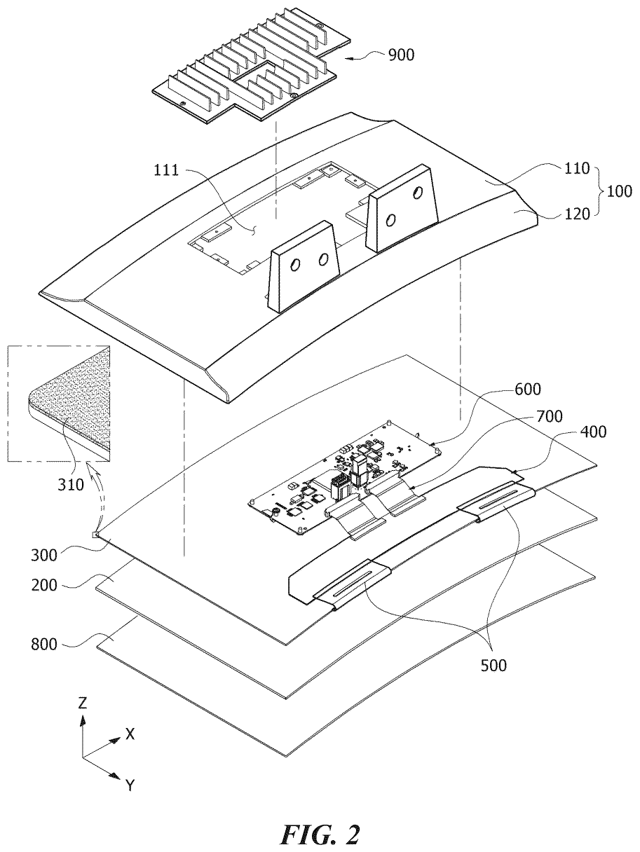

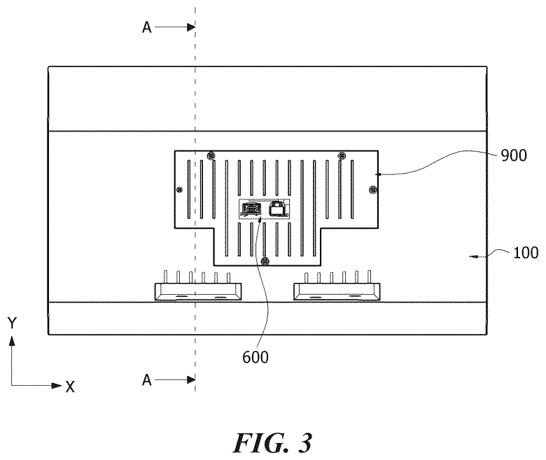

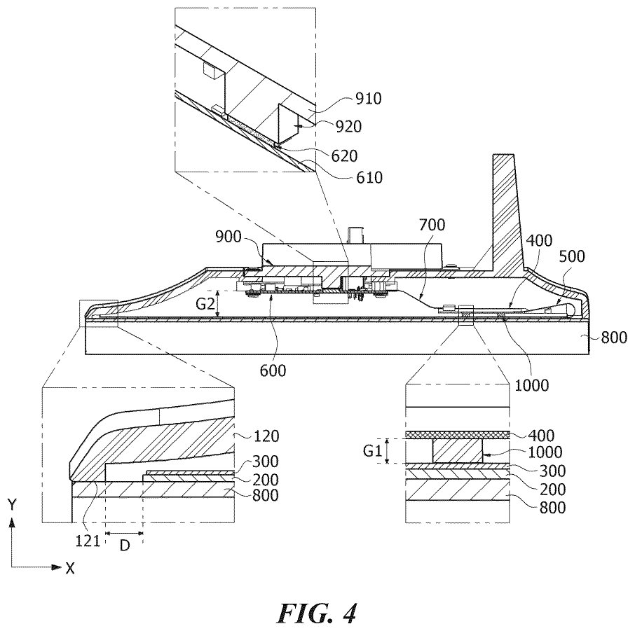

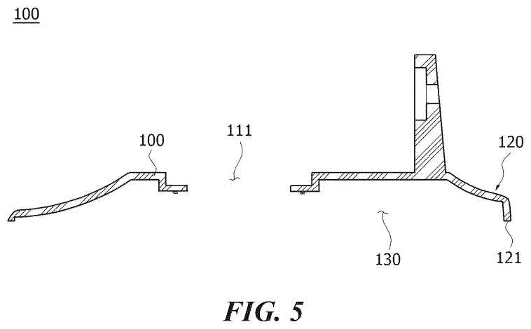

FIG. 1 is a perspective view illustrating a display device according to one embodiment of the present specification, FIG. 2 is an exploded perspective view illustrating the display device according to one embodiment of the present specification, FIG. 3 is a plan view illustrating the display device according to one embodiment of the present specification, FIG. 4 is a cross-sectional view illustrating a cross-section taken along line A-A of FIG. 3, and FIG. 5 is a cross-sectional view illustrating a housing of a display device according to one embodiment of the present specification.

Referring to FIGS. 1 to 5, a display device according to one embodiment of the present disclosure may include a housing 100 having an opening formed in one side thereof, a display panel 200 disposed in the opening 130 of the housing 100, a plate 300 disposed in the rear surface of the display panel 200, a first substrate 400 disposed in the rear surface side of the plate 300, a first flexible film 500 connecting the display panel 200 and the first substrate 400, a second substrate 600 disposed to be spaced apart from the first substrate 400, and a second flexible film 700 connecting the first substrate 400 and the second substrate 600. In this case, the display device according to one embodiment of the present specification may minimize the influence of heat generated in the second substrate 600 on the display panel 200 by arranging the second substrate 600 to be more spaced apart from the plate 300 than the first substrate 400. Here, since the heat generated in the second substrate 600 is relatively higher than the heat generated in the first substrate 400, the temperature of the second substrate 600 may be higher than the temperature of the first substrate 400. In addition, one surface on which the input image is displayed based on the display panel 200 may be called the front surface of the display panel 200, and the surface opposite to the front surface may be called the rear surface.

In addition, the display device according to one embodiment of the present specification may further include a cover glass 800 disposed in front of the display panel.

In addition, the display device according to one embodiment of the present specification may further include a heat sink 900 coupled to the housing 100 to be in contact with the second substrate 600.

The housing 100, the cover glass 800, and the heat sink 900 may form an outer appearance of the display device according to one embodiment of the present specification. In addition, the accommodation space may be formed therein by a combination of the housing 100 and the cover glass 800. Accordingly, as shown in FIG. 4, the display panel 200, the plate 300, the first substrate 400, the first flexible film 500, the second substrate 600, the second flexible film 700, and the like may be disposed in the accommodation space.

Referring to FIGS. 1 to 5, the housing 100 may be formed in a cylindrical shape, and may form an outer appearance of the display device according to one embodiment of the present specification. In addition, the display panel 200, the plate 300, the first substrate 400, the first flexible film 500, the second substrate 600, the second flexible film 700, and the like may be disposed inside the housing 100.

The shape or material of the housing 100 may be variously changed. For example, the housing 100 may be formed of a synthetic resin material forming various shapes, but is not limited thereto. The housing 100 may be formed of a metal material such as aluminum that may withstand high temperatures well. However, in consideration of the degree of freedom of design of the shape of the housing 100 and the heat effect of the second substrate 600 coupled to the housing 100, the housing 100 may be formed of a synthetic resin material such as plastic.

The housing 100 may include a housing body 110 and a sidewall 120 extending to protrude from an edge of the housing body 110. Accordingly, the opening 130 may be formed in the housing 100.

The housing body 110 may be formed in a plate shape and may be disposed to be spaced apart from the plate 300.

In addition, a hole 111 may be formed in the housing body 110, and a heat sink 900 may be disposed in the hole 111. Accordingly, a display device according to one embodiment of the present specification may provide a compact display device by reducing a size in a Z direction through the heat sink 900 disposed in the hole 111. Here, the hole 111 may be referred to as a housing hole or a first hole.

The sidewall 120 may protrude from an edge of the housing body 110 toward the cover glass 800. In addition, the sidewall 120 may include a curved surface in consideration of an object in which the display device is installed. Here, the object may be a dashboard or a center fascia of a vehicle.

In addition, the end 121 of the sidewall 120 may be fixed to the edge of the rear surface of the cover glass 800 using an adhesive member or the like. In this case, the sidewall 120 may be spaced apart from the side surface of the display panel 200 by a predetermined distance D. Accordingly, damage to the display panel 200 may be prevented by the combination of the housing 100 and the cover glass 800.

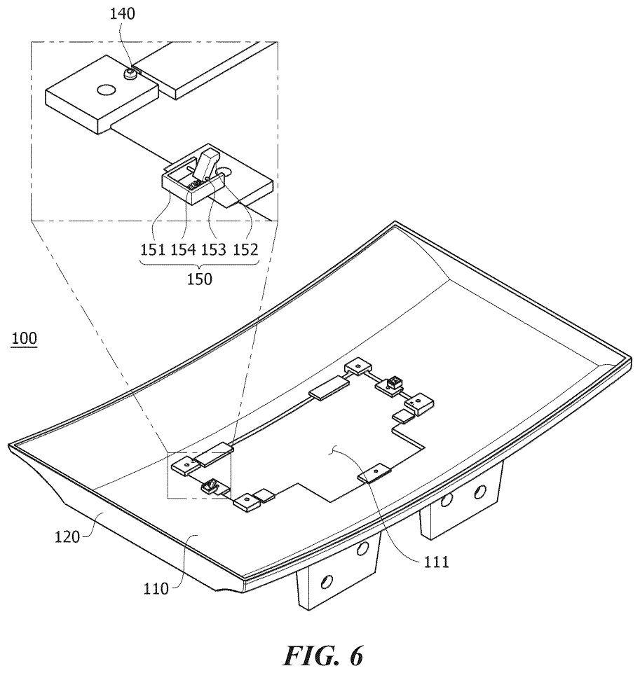

FIG. 6 is a bottom perspective view illustrating a housing of a display device according to one embodiment of the present specification.

Referring to FIG. 6, the housing 100 may include a protrusion 140 and a hook device 150 disposed on the housing body 110. Accordingly, the second substrate 600 may be fixed to the inside of the housing 100 using the protrusion 140 and the hook device 150. Here, the protrusion 140 may be referred to as a housing protrusion or a first protrusion.

The protrusion 140 may be formed to protrude from one side of the inside of the housing body 110. In addition, the protrusion 140 may guide coupling of the housing 100 and the second substrate 600. In this case, at least two protrusions 140 may be formed to correspond to the holes of the second substrate 600. Accordingly, by the combination of the protrusion 140 of the housing 100 and the hole of the second substrate 600, the second substrate 600 may be positioned at a preset position to prevent horizontal flow or movement.

The hook device 150 may be disposed on one side of the inside of the housing body 110 to prevent the flow of the second substrate 600.

Referring to FIG. 6, the hook device 150 may include a hook device body 151 disposed in the housing body 110, a hook 152 rotatably disposed in the hook device body 151, a pin 153 used as a rotation shaft of the hook 152, and an elastic member 154 disposed between the hook 152 and the hook device body 151. Here, the hook device body 151 may be formed in a rectangular frame shape and may be integrally formed with the housing body 110.

By the hook 152 rotating with respect to the pin 153, one side of the hook 152 may be in contact with the circuit board body 610 of the second substrate 600, and one side of the circuit board body 610 may be supported by using the elastic restoring force of the elastic member 154. Accordingly, the hook device 150 may prevent the flow of the second substrate 600.

The display panel 200 may be disposed in the opening 130 of the housing 100 to display an input image. Also, the display panel 200 may be formed in a plate shape having a predetermined thickness, and may include the front surface on which an image is implemented and the rear surface opposite to the front surface. Here, the rear surface may be one surface of the display panel 200 disposed on the upper portion based on the Z direction on the drawing (see FIG. 2).

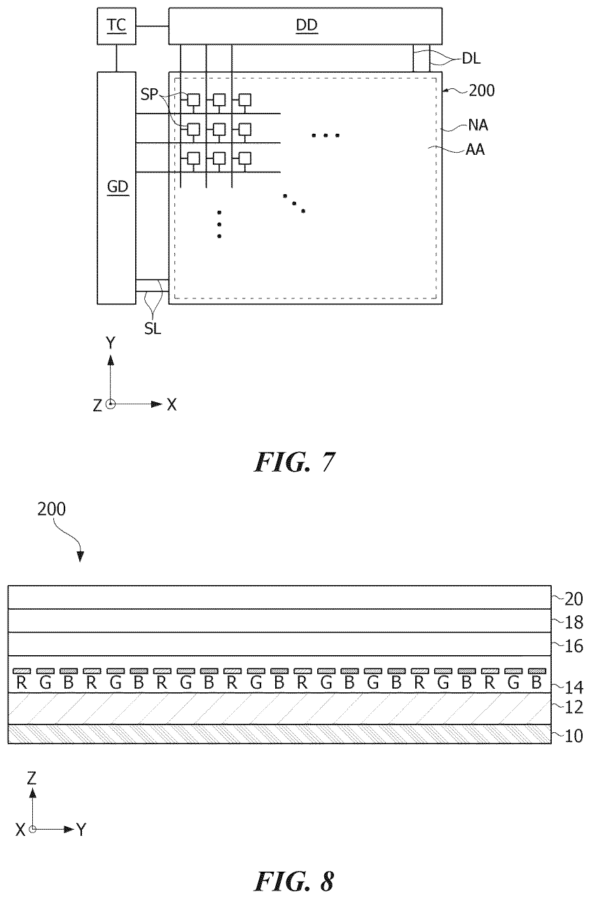

FIG. 7 is a block diagram schematically showing a configuration of a display device according to one embodiment of the present specification.

Referring to FIG. 7, the display device includes a display panel 200 in which a plurality of pixels are arranged in a display area AA, and a driving circuit that drives the pixels.

The display panel 200 may be a panel having a rectangular structure with a length in the X-axis direction, a width in the Y-axis direction, and a thickness in the Z-axis direction. The pixels include a plurality of sub-pixels SP with different colors. The driving circuit includes a data driver DD, a gate driver GD, and a timing controller TC that controls the gate driver GD and the data driver DD. The display area AA on which an input image is displayed on the display panel 200 may be a screen visible from the front surface of the display panel 200. Here, the width and length of the display panel 200 may be set to various design values depending on the application fields of the display device. In addition, the X-axis direction may mean a longitudinal direction or a horizontal direction, the Y-axis direction may mean a width direction or a vertical direction, and the Z-axis direction may mean an up-down direction or a thickness direction. In addition, the X-axis direction, Y-axis direction, and Z-axis direction may be perpendicular to each other, but may also mean different directions that are not perpendicular to each other. Accordingly, each of the X-axis direction, Y-axis direction, and Z-axis direction may be described as one of a first direction, a second direction, and a third direction. In addition, the plane extending in the X-axis direction and the Y-axis direction may mean a horizontal plane.

The input image is displayed on the subpixels SP disposed in the display area AA of the display panel 200. Each of the subpixels SP includes a light emitting element and a pixel circuit that drives the light emitting element. The light emitting element may be a light emitting diode (LED) or a micro light emitting diode (micro LED).

On the display panel 200, a plurality of scan wirings (in other words, scan lines) SL and a plurality of data wirings (in other words, data lines) DL are arranged to cross each other. Each of the subpixels SP is connected to a scan wiring SL and a data wiring DL. Power supply wirings (in other words, power supply lines) omitted in FIG. 7 may be connected to each of the subpixels SP. In a display panel 200, a non-display area NA may be disposed outside the display area AA.

The gate driver GD supplies scan signals to the scan wirings SL in response to a gate control signal provided by the timing controller TC. The gate driver GD may be disposed at least in the non-display area NA of the display panel 200, as shown in FIG. 7, or disposed in the display area AA.

The data driver DD converts the image data received from the timing controller TC into a reference compensation voltage and outputs a data voltage in response to a data control signal provided by the timing controller TC. The data voltage output from the data driver DD is supplied to the data wirings DL.

The timing controller TC sequences image data input from the outside and supplies the sequenced image data to the data driver DD. The timing controller TC may generate gate control signals and data control signals based on timing signals synchronized with input image signals, for example, dot clock signals, data enable signals, and horizontal/vertical synchronization signals. The timing controller TC supplies the gate control signals to the gate driver GD and the data control signals to the data driver DD to control the timing of the operation of the gate driver GD and the data driver DD.

The non-display area NA may have link wirings (in other words, link lines) and pad electrodes disposed therein to transmit signals to the subpixels SP in the display area AA. Furthermore, one or more of a gate driver IC in which circuits for the gate driver GD are integrated and a data driver IC in which circuits for the data driver DD are integrated may be disposed in the non-display area NA. The non-display area NA may be located on the rear surface of the display panel 200, i.e., on the rear surface where there are no subpixels SP, or it may be minimized to the extent that it is invisible when an image is displayed on the display panel 200.

The drivers such as the gate driver GD, the data driver DD, and the timing controller TC may be connected to the display panel 200 in a variety of ways. For example, the gate driver GD may be disposed in a gate in panel (GIP) fashion in the non-display area NA, or in a gate in active area (GIA) fashion between subpixels SP in the display area AA. For example, the data driver DD and the timing controller TC may be formed on separate flexible films and printed circuit boards (hereinafter referred to as “PCB”), and the data driver DD and the timing controller TC may be electrically connected to the display panel 200 by bonding the flexible films and the PCBs to pad electrodes formed on the non-display area NA of the display panel 200.

FIG. 8 is a cross-sectional view schematically showing a cross-sectional structure of a display area of a display device according to one embodiment of the present specification.

Referring to FIG. 8, the display panel 200 may include a circuit layer 12 disposed on the substrate 10, and a light emitting device layer 14 disposed on the circuit layer 12. Also, the display panel 200 may include an encapsulation layer 16 disposed on the light emitting device layer 14, a touch sensor layer 18 formed on the encapsulation layer 16, and a color filter layer 20 disposed on the touch sensor layer 18.

The substrate 10 may be formed of an insulating material or a material having flexibility. For example, the substrate 10 may be made of glass, metal, plastic, or the like.

The circuit layer 12 may include a pixel circuit connected to wirings such as data lines, gate lines, power lines, and the like, a gate driver connected to the gate lines, and the like. In addition, the wiring and circuit elements of the circuit layer 12 may include a plurality of insulating layers, two or more metal layers separated from each other with an insulating layer interposed therebetween, and an active layer including a semiconductor material.

The light emitting device layer 14 may include a light emitting device driven by a pixel circuit. In addition, the light emitting device may include a red light emitting device, a green light emitting device, and a blue light emitting device. In another embodiment, the light emitting device layer 14 may include a white light emitting device and a color filter. Light emitting devices of the light emitting device layer 14 may be covered by a protective layer including an organic film and a protective film.

The encapsulation layer 16 covers the light emitting device layer 14 to seal the circuit layer 12 and the light emitting device layer 14. Here, the encapsulation layer 16 may have a multi-insulating film structure in which an organic film and an inorganic film are alternately stacked. In this case, the inorganic film blocks the penetration of moisture or oxygen. The organic film planarizes the surface of the inorganic film. When the organic film and the inorganic film are stacked in several layers, a movement path of moisture or oxygen is longer than that of a single layer, and thus the penetration of moisture/oxygen affecting the light emitting device layer 14 may be effectively blocked.

The touch sensor layer 18 may include capacitive touch sensors that sense a touch input based on a change in capacity before and after the touch input. The touch sensor layer 18 may include metal wiring patterns and insulating films forming capacities of touch sensors. The insulating films may insulate intersecting portions of the metal wiring patterns and may planarize the surface of the touch sensor layer.

A polarizer omitted in the drawing may be attached onto the touch sensor layer 18. The polarizer may convert polarization of external light reflected by the metal patterns of the circuit layer 12 to improve visibility and contrast ratio. Here, the polarizer may be implemented as a linear polarizer, and a polarizer or a circular polarizer in which phase delay film are bonded. In addition, the cover glass 800 may be attached onto the polarizer.

The color filter layer 20 may be formed on the touch sensor layer 18.

The color filter layer 20 may include red, green, and blue color filters. Also, the color filter layer 20 may further include a black matrix pattern. The color filter layer 20 may absorb a portion of the wavelength of light reflected from the circuit layer 12 to replace the role of the polarizer and increase color purity. In the present embodiment, the color filter layer 20 having a higher light transmittance than the polarizer may be applied to the display panel 200 to improve light transmittance of the display panel 200 and improve thickness and flexibility of the display panel 200. The cover glass 800 may be adhered to the color filter layer 20.

The color filter layer 20 may include an organic film covering the color filter and the black matrix pattern. An extension portion of this organic film may cover the leftover portion of the inorganic film or the panel substrate 10 at a bezel area of the display panel 200, that is, at an edge area thereof.

The plate 300 may be formed to have a predetermined thickness and may be formed in a shape that corresponds to the back surface of the display panel 200. The plate 300 may be arranged between the display panel 200 and the substrate 400 and 600.

The plate 300 may support and protect the display panel 200 by being attached to the back surface of the display panel 200. For example, the fixation of the plate 300 to the back surface of the display panel 200 through the adhesive member may protect one side of the display panel 200 while supporting the display panel 200. The adhesive member here may be formed of an adhesive material, such as a foam tape, and may be arranged along an edge of the plate 300.

The plate 300 may be manufactured from a material having rigid properties and high thermal conductivity, for example, from a metal material, such as aluminum (Al), a copper (Cu), zinc (Zn), silver (Ag), gold (Au), iron (Fe), stainless steel (STS), or invar. Accordingly, a uniform temperature distribution across the display panel 200 may be achieved by dispersing heat generated within the display panel 200 while minimizing variation of temperature among areas of the display panel 200.

In addition, a coating layer 310 may be formed on the plate 300 in a manner that protects against damage or the like due to corrosion, a chemical material, or the like. For example, the coating layer 310 may be formed on only one surface of the plate 300, taking into consideration exterior aesthetic appeal, productivity, heat dissipation performance, and the like of the plate 300.

The coating layer 310 on the plate 300 may be formed of an insulation material through electric-deposition coating process, but is not necessarily limited thereto. The electric-deposition coating here is one of coating methods in which a coating target serving as a positive or negative electrode is immersed in a solution containing water-soluble paint for electric deposition and in which a film of paint is electrically deposited on a surface of the coating target by causing direct current to flow between the coating target and the opposite electrode.

In addition, the coating layer 310 may be provided in black color according to the blackbody heat radiation principle. Accordingly, a radiation ratio of the coating layer 310 reaches or exceeds 80%. The blackbody here refers to an object that completely absorbs even radiation in a range of all wavelengths, i.e., an object that absorbs all radiant energy incident from the outside and has a maximum radiation (absorption) ratio of 1 without any surface reflection, that is, with only re-radiation possible. The heat radiation emitted from the blackbody is referred to as blackbody radiation. In practice, it is difficult to manufacture a perfect blackbody having a radiation efficiency of 1, but it is feasible to increase radiation efficiency in a manner that is close to that of a blackbody. For example, charcoal or soot is close in radiation efficiency to the blackbody.

Therefore, a black-colored coating layer 310 formed by the electric-deposition coating may increase the solidity of the film of paint and may improve the thermal transfer properties and heat radiation ratio of the plate 300. In addition, the plate 300 may block or minimize local transfer of heat generated in the substrate 400 and 600 to the display panel 200 by being arranged between the display panel 200 and the substrate 400 and 600.

The first substrate 400 may be disposed on the rear surface of the display panel 200. In addition, the plate 300 may be disposed between the display panel 200 and the first substrate 400. Accordingly, the first substrate 400 may be disposed on the rear surface of the plate 300.

The first substrate 400 may include a plate-shaped circuit board body and circuit elements mounted on the circuit board body. And, heat may be generated in circuit elements of the first substrate 400 by driving the display panel 200.

In the display device according to one embodiment of the present specification, the separation member 1000 is disposed between the plate 300 and the first substrate 400 to prevent or reduce heat generated from the first substrate 400 from affecting the display panel 200.

The separation member 1000 may separate the first substrate 400 from the plate 300 by a predetermined distance G1. Here, an adhesive member may be used as the separation member 1000. For example, a double-sided tape having a predetermined thickness may be used as the separation member 1000. Accordingly, the separation member 1000 may prevent direct contact between the plate 300 and the first substrate 400, thereby minimizing heat effects between the plate 300 and the first substrate 400.

A plurality of separation members 1000 may be disposed between the plate 300 and the first substrate 400 to be spaced apart from each other.

In the display device according to one embodiment of the present specification, the influence of the heat generated in the first substrate 400 on the plate 300 may be minimized by forming the air gap G1 in the region in which the separation member 1000 is not disposed between the plate 300 and the first substrate 400. For example, the air gap G1 and the air moving through the air gap G1 may lower the temperature of the first substrate 400. Here, the air gap G1 formed in the region between the plate 300 and the first substrate 400 may be referred to as a first gap or a first air gap.

The at least one first flexible film 500 may electrically connect the display panel 200 to the first substrate 400. In detail, the first flexible film 500 may connect the pad electrodes of the display panel 200 to the output terminals of the first substrate 400. In this case, the first flexible film 500 may be bonded to the display panel 200 through an anisotropic conductive film (ACF). Here, the first flexible film 500 may be a flexible printed circuit board (FPCB), and may be a chip-on film (COF) on which an IC in which circuits of the data driver DD and/or the gate driver GD are integrated is mounted, but is not limited thereto. And, the first flexible film 500 may be referred to as a first flexible circuit film.

The second substrate 600 may be disposed inside the housing 100, and may be fixed inside the housing 100 using a fastening member such as a bolt or a screw.

The second substrate 600 may be further spaced apart from the plate 300 than the first substrate 400.

In the display device according to one embodiment of the present specification, elements that generate relatively large amounts of heat during driving are disposed on the second substrate 600 and the second substrate 600 is disposed to be spaced apart from the plate 300 more than the first substrate 400, thereby minimizing the influence of heat generated in the second substrate 600 on the display panel 200.

Referring to FIG. 4, since the second substrate 600 is disposed on the inner bottom surface of the housing body 110, the second substrate 600 may be more spaced apart from the plate 300 than the first substrate 400. In detail, since the second substrate 600 is coupled to the housing body 110 disposed to be spaced apart from the plate 300, an air gap (G2) may be formed between the second substrate (600) and the plate (300), and the air moving through the air gap G2 may lower the temperature of the second substrate 600. Here, the air gap G2 formed between the second substrate 600 and the plates 300 may be referred to as a second gap or a second air gap.

In this case, unlike the first substrate 400 disposed adjacent to the plate 300, since the second substrate 600 is coupled to the housing body 110, the second air gap may be greater than the first air gap. Accordingly, even though the temperature of the heat generated in the second substrate 600 is relatively higher than the temperature of the heat generated in the first substrate 400, the heat effect by the second substrate 600 with respect to the plate 300 is relatively lower than the heat effect by the first substrate 400.

Furthermore, since the second substrate 600 may be formed of a synthetic resin material such as plastic having relatively low thermal conductivity, and the elements that generate heat may be disposed on the rear surface of the second substrate 600, which is the opposite surface of the front surface, rather than the front surface of the second substrate 600 disposed to face the plate 300, it is difficult for the heat generated by the elements to directly affect the display panel 200. Here, the front surface of the second substrate 600 may be referred to as a first substrate surface, and the rear surface, which is the opposite surface of the front surface, may be referred to as a second substrate surface.

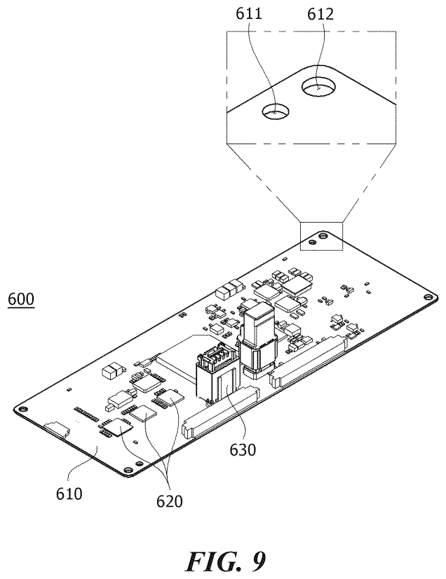

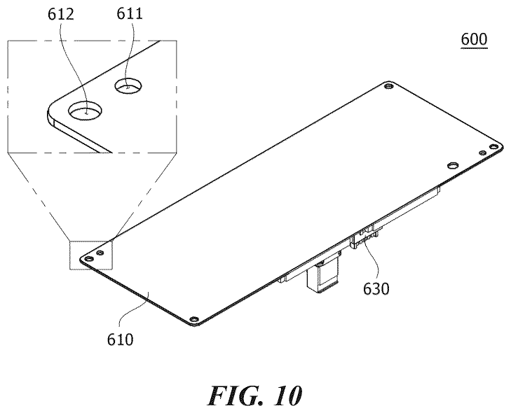

FIG. 9 is a perspective view illustrating a second substrate of a display device according to one embodiment of the present specification, and FIG. 10 is a bottom perspective view illustrating a second substrate of a display device according to one embodiment of the present specification.

Referring to FIGS. 9 and 10, the second substrate 600 may include a plate-shaped circuit board body 610, a plurality of elements 620 and circuit wiring (not shown) disposed on the circuit board body 610, a plurality of holes formed in the circuit board body 610, and a connector 630. In this case, since the second substrate 600 is formed to have a larger area than the first substrate 400, more elements 620 may be disposed on the second substrate 600 than the first substrate 400.

The circuit board body 610 may be formed in a plate shape. In addition, the circuit board body 610 is formed of a synthetic resin material such as plastic, so that heat generated from the elements 620 may be minimized from being transferred to the display panel 200. In addition, the circuit board body 610 may be fixed to the housing body 110 using a fastening member.

A plurality of holes penetrating the circuit board body 610 may include a first hole 611 and a second hole 612. The first hole 611 and the second hole 612 may be formed at the edge of the circuit board body 610 in consideration of the assembly of the housing 100 and the second substrate 600 and the arrangement of the elements 620.

The first hole 611 may be coupled to the protrusion 140 of the housing 100 to guide the circuit board body 610 to be positioned at a preset position. Here, at least two first holes 611 may be formed in the circuit board body 610 so that the circuit board body 610 is guided at a preset position.

The second hole 612 may be a hole through which a fastening member passes for fastening the housing 100 and the second substrate 600. At least two second holes 612 may be formed in the circuit board body 610 in consideration of fixing the circuit board body 610.

A plurality of elements 620 and circuit wiring may be disposed on the circuit board body 610. In addition, heat may be generated in the plurality of elements 620 and the circuit wiring by driving the display device according to one embodiment of the present specification. A plurality of elements 620 that generate more heat than circuit wiring may be disposed on the rear surface of the circuit board body 610 in consideration of a heat effect on the display panel 200.

The connector 630 may be disposed on the rear surface of the circuit board body 610. In addition, an external device such as an external power source may be coupled to the connector 630. In this case, the connector 630 may penetrate the through hole 911 of the heat sink 900, and may be protected by the heat dissipation fins 930 formed to protrude from the periphery of the through hole 911.

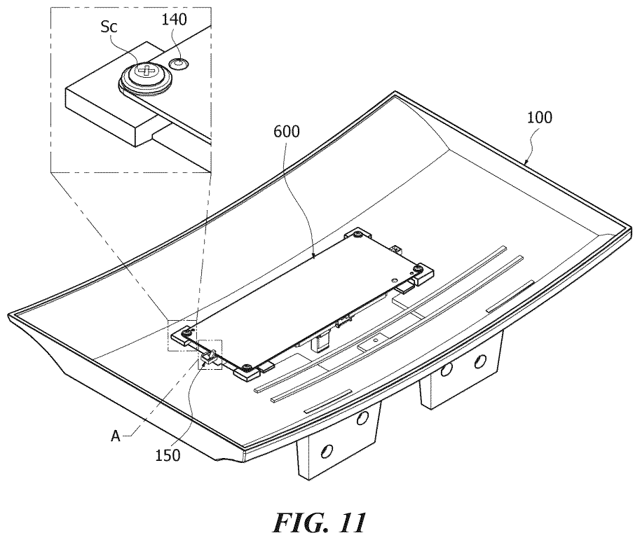

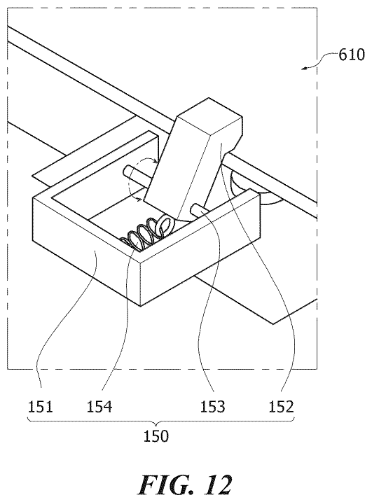

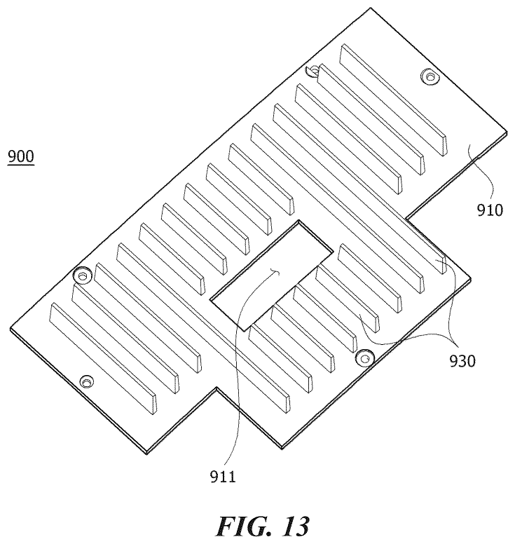

FIG. 11 is a view illustrating an arrangement relationship between a housing and a second substrate of a display device according to one embodiment of the present specification, and FIG. 12 is an enlarged view of an area A of FIG. 11.

Referring to FIGS. 11 and 12, the second substrate 600 may be assembled inside the housing 100 by using the coupling between the protrusion 140 of the housing 100 and the first hole 611 and the hook device 150. And, the second substrate 600 may be fixed to the housing 100 through a coupling member passing through the second hole 612. Here, as the coupling member Sc, a bolt, a screw, or the like may be used.

By inserting the first hole 611 of the second substrate 600 into the protrusion 140 of the housing 100 in a state in which the hook 152 rotating with respect to the pin 153 is tilted outward, the second substrate 600 may be positioned at a preset position. In this case, the hook 152 rotating with respect to the pin 153 may support one side of the circuit board body 610 by an elastic restoring force of the elastic member 154. Therefore, the coupling between the protrusion 140 of the housing 100 and the first hole 611 and the hook device 150 may prevent the flow of the second substrate 600. And, the second substrate 600 may be fixed to the inner surface of the housing body 110 using the fastening member Sc.

The at least one second flexible film 700 may electrically connect the first substrate 400 and the second substrate 600. In this case, the second flexible film 700 may be bonded to the first substrate 400 and the second substrate 600 through an anisotropic conductive film (ACF), but is not necessarily limited thereto. Here, the second flexible film 700 may be a flexible printed circuit board (FPCB), and may be a chip-on film (COF) on which an IC in which a circuit of the data driver DD and/or the gate driver GD is integrated is mounted, but is not limited thereto. In addition, the second flexible film 700 may be referred to as a second flexible circuit film.

The cover glass 800 may be disposed on the front surface of the display panel 200 to protect the display panel 200. In this case, the cover glass 800 may be attached to the front surface of the display panel 200 using an adhesive member.

The horizontal area of the cover glass 800 may be formed larger than the horizontal area of the display panel 200. Accordingly, even if the display panel 200 is attached to the rear surface of the cover glass 800, the edge of the rear surface of the cover glass 800 may be exposed, and the end 121 of the housing 100 may be disposed on the exposed edge. In this case, since the sidewall 120 may be disposed to be spaced apart from the side surface of the display panel 200 by a predetermined distance D, even if the end 121 of the housing 100 is fixed to the rear surface of the cover glass 800 by using the adhesive member, damage to the display panel 200 may be prevented.

The heat sink 900 may be disposed to be in contact with the second substrate 600 to radiate heat generated from the second substrate 600 to the outside. In this case, the heat sink 900 may be disposed in the hole 111 formed in the housing body 110 to implement a compact display device.

FIG. 13 is a view illustrating a heat sink of a display device according to one embodiment of the present specification.

Referring to FIGS. 4 and 13, the heat sink 900 may include a heat sink body 910, at least one protrusion 920 formed to protrude from the front surface of the heat sink body 910, and a plurality of heat dissipation fins 930 formed to protrude from the front surface of the heat sink body 910. Here, the heat sink body 910, the protrusion 920, and a plurality of heat dissipation fins 930 may be integrally formed and may be formed of a metal material.

The heat sink body 910 may be formed in a plate shape. In addition, the heat sink body 910 may be disposed in the hole 111 of the housing 100 to implement a compact display device.

The heat sink body 910 may include a through hole 911 formed to penetrate in the Z direction. The through hole 911 may be formed to correspond to the connector 630 of the second substrate 600. Accordingly, the connector 630 may be disposed to penetrate the through hole 911.

The protrusion 920 may be formed to protrude from one side of the heat sink body 910 toward the second substrate 600. Here, the protrusion 920 of the heat sink 900 may be referred to as a second protrusion or a heat sink protrusion, and may be formed to protrude from the front surface of the plate-shaped heat sink body 910. The front surface of the heat sink body 910 may mean a surface disposed to face the second substrate 600.

The protrusion 920 may be disposed to be in contact with the second substrate 600, and heat generated from the second substrate 600 may move to the heat sink body 910 through the protrusion 920 to be dissipated. As illustrated in FIG. 4, the protrusion 920 may be in contact with the element 620 of the second substrate 600 that generates a large amount of heat, and may activate heat conduction by using a heat conducting member such as thermal grease. Here, for example, the protrusion 920 is in contact with one element 620 disposed on the second substrate 600, but is not limited thereto. For example, the heat sink 900 may include a plurality of protrusions 920, and at least one of the plurality of protrusions 920 may be in contact with at least one of the plurality of elements 620.

The plurality of heat dissipation fins 930 may be formed to protrude from the rear surface of the heat sink body 910 and may be exposed to the outside. Accordingly, the plurality of heat dissipation fins 930 may improve the heat dissipation performance of the heat sink 900.

In addition, a plurality of heat dissipation fins 930 may be disposed around the through hole 911 to protect the connector 630 disposed in the through hole 911.

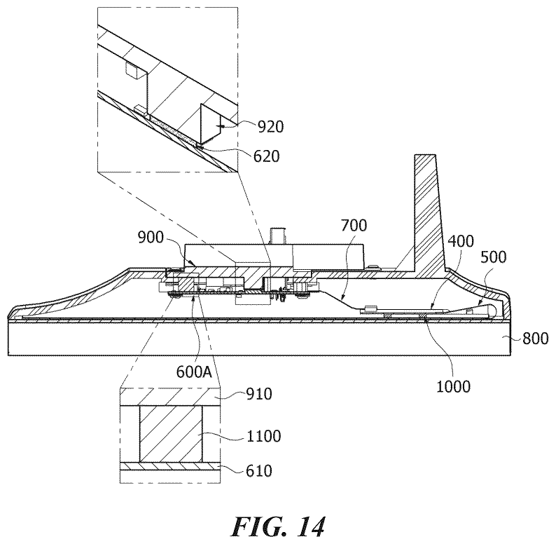

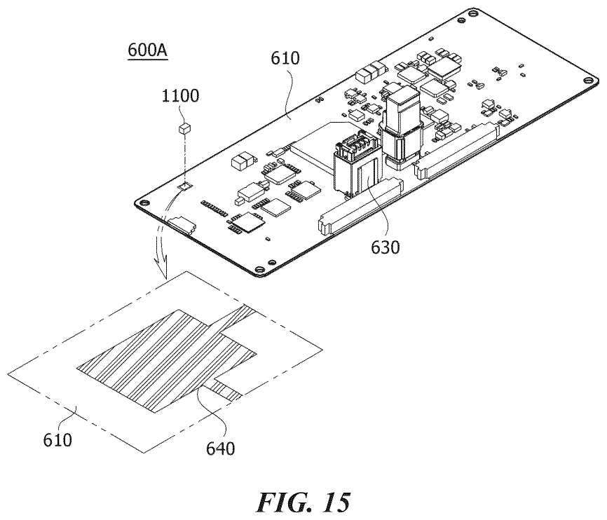

FIG. 14 is a view illustrating a display device according to another embodiment of the present specification, and FIG. 15 is a view illustrating an arrangement relationship between a second substrate and a ground member of a display device according to another embodiment of the present specification.

When comparing a display device according to one embodiment of the present specification illustrated in FIG. 4 with a display device according to another embodiment of the present specification illustrated in FIG. 14, the display device according to another embodiment of the present specification illustrated in FIG. 14 is different in that it further includes a ground member 1100 disposed between the second substrate 600A and the heat sink 900. Here, the display device according to one embodiment of the present specification illustrated in FIG. 4 may be the display device according to a first embodiment, and the display device according to another embodiment of the present specification illustrated in FIG. 14 may be the display device according to a second embodiment.

In describing the display device according to the second embodiment, since the same components as the display device according to the first embodiment may use the same reference numerals, a specific description thereof will be omitted.

Referring to FIGS. 14 and 15, a display device according to a second embodiment may include a housing 100 having an opening formed at one side thereof, a display panel 200 disposed at the opening 130 of the housing 100, a plate 300 disposed at the rear surface of the display panel 200, a first substrate 400 disposed at the rear surface side of the plate 300, a first flexible film 500 that connects the display panel 200 and the first substrate 400, a the second substrate 600A disposed to be spaced apart from the first substrate 400, a second flexible film 700 that connects the first substrate 400 and the second substrate 600, a cover glass 800 disposed at the front surface of the display panel, a heat sink 900 disposed to be in contact with one side of the second substrate 600A, and a ground member 1100 disposed between the second substrate 600A and the heat sink 900.

The second substrate 600A may include a plate-shaped circuit board body 610, a plurality of elements 620 and a circuit wiring (not shown) disposed on the circuit board body 610, a plurality of holes formed in the circuit board body 610, a connector 630, and a ground pattern 640 disposed on the circuit board body 610 to correspond to the ground member 1100.

The ground pattern 640 may be disposed on the rear surface of the circuit board body 610 and may be formed in a shape corresponding to the ground member 1100.

The ground pattern 640 may be electrically connected to the elements 620 of the second substrate 600A through circuit wiring. And, the ground pattern 640 may overlap the ground member 1100 in the Z direction so as to be in contact with the ground member 1100.

The ground member 1100 may be disposed between the ground pattern 640 of the second substrate 600A and the front surface of the heat sink body 910 to electrically connect the ground pattern 640 to the heat sink body 910. Here, the ground member 1100 may be formed of a conductive material, and one side of the ground member 1100 may contact the ground pattern 640 and the other side of the ground member 1100 may contact the heat sink body 910. Accordingly, the display device according to the second embodiment may implement a ground structure in which the second substrate 600A and the heat sink 900 are connected using the ground member 1100.

The ground member 1100 may be formed in a structure having an elastic restoring force, but is not limited thereto. For example, the ground member 1100 may be formed to include particles of a plurality of metal materials in a synthetic resin material having an elastic restoring force.

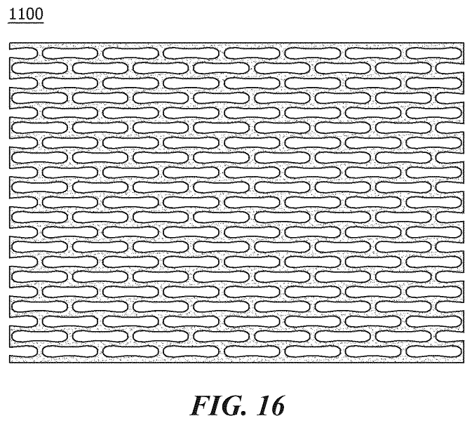

FIG. 16 is a view illustrating a cross-section of a ground member disposed in a display device according to another embodiment of the present specification.

Referring to FIG. 16, the ground member 1100 may be formed in a structure having an elastic restoring force. For example, the ground member 1100 may be formed to have a net-shaped pattern, and may be contracted or relaxed by a predetermined load. Accordingly, since the ground member 1100 has an elastic restoring force, even if a predetermined load is applied to the heat sink 900, damage to the second substrate 600A due to the load may be prevented.

The embodiments of the present disclosure described above will be briefly described as follows.

A display device according to the embodiments of the present disclosure includes: a housing having an opening formed on one side thereof; a display panel disposed in the opening; a first substrate disposed on the rear surface of the display panel; a first flexible film configured to connect the display panel and the first substrate; a second substrate disposed to be spaced apart from the first substrate; and a second flexible film configured to connect the first substrate and the second substrate, wherein the second substrate is disposed to be more spaced apart from the display panel than the first substrate.

The display device according to the embodiments of the present disclosure may further include a metal plate disposed on the rear surface of the display panel.

In the display device according to the embodiments of the present disclosure, the first substrate may be spaced apart from the plate by a predetermined interval by a spaced member.

The display device according to the embodiments of the present disclosure may further include: a cover glass disposed in front of the display panel, wherein the housing may include a housing body, and a sidewall formed to protrude from an edge of the housing body, and an end portion of the sidewall may be in contact with an edge of the cover glass.

In the display device according to the embodiments of the present disclosure, a side surface of the display panel may be disposed to be spaced apart from the sidewall.

In the display device according to the embodiments of the present disclosure, the second substrate may include a plate-shaped circuit board body and a plurality of elements disposed on the circuit board body, wherein the housing may include a protrusion formed to protrude from the housing body, and wherein the protrusion may be coupled to a hole formed in the circuit board body.

In the display device according to the embodiments of the present disclosure, the second substrate may include a plate-shaped circuit board body and a plurality of elements disposed on the circuit board body, wherein the housing may include a hook device configured to prevent the flow of the circuit board body.

In the display device according to the embodiments of the present disclosure, the hook device may include a hook device body disposed in the housing body of the housing, a hook rotatably disposed in the hook device body, and an elastic member disposed between the hook and the hook device body, wherein the hook may support one side of the circuit board body by using the elastic restoring force of the elastic member.

The display device according to the embodiments of the present disclosure may further include a heat sink coupled to the housing, wherein a protrusion portion of the heat sink may be in contact with an element disposed on the second substrate.

In the display device according to the embodiments of the present disclosure, the housing may include a housing body disposed to be spaced apart from the display panel, and a sidewall formed to protrude from an edge of the housing body, wherein the heat sink may be disposed in a hole formed in the housing body.

The display device according to the embodiments of the present disclosure may further include a ground member disposed between the second substrate and the heat sink, wherein one side of the ground member may contact a ground pattern of the second substrate and the other side thereof contacts the heat sink.

In the display device according to the embodiments of the present disclosure, the ground member may be formed in a net structure having an elastic restoring force.

In the display device according to the embodiments of the present disclosure, the second substrate may include a plate-shaped circuit board body, and a plurality of elements and a connector disposed on the circuit board body, wherein the elements and the connector may be disposed on the rear surface of the circuit board body.

The display device according to the embodiments of the present disclosure may further include a heat sink coupled to the housing, wherein the heat sink may include a heat sink body and a through hole formed in the heat sink body, and the connector may penetrate the through hole.

In the display device according to the embodiments of the present disclosure, the heat sink may further include a plurality of heat dissipation fins formed to protrude from the rear surface of the heat sink body.

A display device according to the embodiments of the present disclosure may include: a housing having an opening formed on one side thereof; a display panel disposed in the opening; a first substrate disposed on the rear surface of the display panel; a first flexible film configured to connect the display panel and the first substrate; a second substrate disposed to be spaced apart from the first substrate; a second flexible film configured to connect the first substrate and the second substrate, and a cover glass disposed in front of the display panel, wherein the housing may include a housing body and a sidewall protruding from an edge of the housing body to contact an edge of the cover glass, and wherein the second substrate may be coupled to the housing body.

In the display device according to the embodiment of the present disclosure, the housing may include a protrusion formed to protrude from the housing body, wherein the protrusion is coupled to a hole formed in the circuit board body of the second substrate.

In the display device according to the embodiment of the present disclosure, the housing may a hook device configured to prevent the flow of the circuit board body.

The objects to be achieved by the present disclosure, the means for achieving the objects, and effects of the present disclosure described above do not specify essential features of the claims, and thus, the scope of the claims is not limited by the present disclosure.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

DESCRIPTION OF REFERENCE NUMERALS

| | |
|---|---|
| 100: | housing |
| 200: | display panel |
| 300: | plate |
| 400: | first substrate |
| 500: | first flexible film |
| 600, 600A: | second substrate |
| 700: | second flexible film |
| 800: | cover glass |
| 900: | heat sink |
| 1000: | separation member |
| 1100: | ground member |

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a housing having a side;
an opening in the side of the housing;
a display panel disposed in the opening and having a rear surface;
a first substrate disposed on the rear surface of the display panel;
a first flexible film configured to connect the display panel and the first substrate;
a second substrate spaced apart from the first substrate; and
a second flexible film configured to connect the first substrate and the second substrate,
wherein the second substrate is spaced further from the display panel than the first substrate.

2. The display device of claim 1, further comprising:
a metal plate disposed on the rear surface of the display panel.

3. The display device of claim 2, further comprising:
a separation member between the first substrate and the metal plate,
wherein the first substrate is spaced apart from the metal plate by the separation member.

4. The display device of claim 1, further comprising:
a cover glass disposed on a front surface of the display panel,
wherein the housing includes a housing body and a sidewall extending from an edge of the housing body, and
wherein an end portion of the sidewall is in contact with an edge of the cover glass.

5. The display device of claim 4, wherein a side surface of the display panel is spaced apart from the sidewall.

6. The display device of claim 4, wherein the second substrate includes a plate-shaped circuit board body and a plurality of elements disposed on the circuit board body,
wherein the housing includes a protrusion extending from the housing body, and
wherein the protrusion is coupled to a hole in the circuit board body.

7. The display device of claim 3, wherein the second substrate includes a plate-shaped circuit board body and a plurality of elements disposed on the circuit board body, and
wherein the housing includes a hook assembly configured to prevent movement of the circuit board body.

8. The display device of claim 7, wherein the hook assembly includes a hook body disposed in the housing body of the housing, a hook rotatably disposed in the hook device body, and an elastic member disposed between the hook and the hook body, and
wherein the hook supports a side of the circuit board body via an elastic restoring force of the elastic member.

9. The display device of claim 1, wherein the second substrate includes a plate-shaped circuit board body, and the second substrate further includes a plurality of elements and a connector disposed on the circuit board body, and
wherein the plurality of elements and the connector are disposed on a rear surface of the circuit board body.

10. The display device of claim 9, further comprising:
a heat sink coupled to the housing,
wherein the heat sink includes a heat sink body and a through hole in the heat sink body, and
wherein the connector penetrates the through hole.

11. The display device of claim 10, wherein the heat sink further includes a plurality of heat dissipation fins extending from a rear surface of the heat sink body.

12. A display device, comprising:
a housing having a side;
an opening in the side of the housing;
a display panel disposed in the opening and having a rear surface;
a first substrate disposed on the rear surface of the display panel;
a first flexible film configured to connect the display panel and the first substrate;
a second substrate spaced apart from the first substrate;
an element disposed on the second substrate;
a second flexible film configured to connect the first substrate and the second substrate; and
a heat sink coupled to the housing and including a protrusion,
wherein the protrusion of the heat sink is in contact with the element disposed on the second substrate, and
wherein the second substrate is spaced further from the display panel than the first substrate.

13. The display device of claim 12, wherein the housing includes a housing body disposed to be spaced apart from the display panel, and the housing further includes a sidewall protruding from an edge of the housing body, the housing body including a hole, and
wherein the heat sink is disposed in the hole in the housing body.

14. The display device of claim 12, further comprising:
a ground disposed between the second substrate and the heat sink,
wherein a first side of the ground contacts a ground pattern of the second substrate and a second side of the ground contacts the heat sink.

15. The display device of claim 14, wherein the ground has a net structure having an elastic restoring force.

16. A display device, comprising:
a housing having an opening;
a display panel disposed in the opening of the housing;
a first substrate disposed on a rear surface of the display panel;
a first flexible film configured to connect the display panel and the first substrate;
a second substrate spaced apart from the first substrate;
a second flexible film configured to connect the first substrate and the second substrate, and
a cover glass disposed on a front surface of the display panel,
wherein the housing includes a housing body and a sidewall protruding from an edge of the housing body, the sidewall in contact with an edge of the cover glass, and
wherein the second substrate is coupled to the housing body.

17. The display device of claim 16, wherein the housing includes a protrusion protruding from the housing body, and
wherein the protrusion is coupled to a hole in a circuit board body of the second substrate.

18. The display device of claim 17, wherein the housing includes a hook device configured to prevent movement of the circuit board body.
